(19) United States
(12) Patent Application Publication
(10) Pub. No.: US 2016/0351813 A1
(43) Pub. Date: Dec. 1, 2016

(54) MANUFACTURING METHOD OF THIN FILM TRANSISTOR AND THIN FILM TRANSISTOR , ARRAY SUBSTRATE

(71) Applicants: BOE Technology Group Co., Ltd., Beijing (CN); Ordos Yuansheng Optoelectronics Co., Ltd., Inner Mongolia (CN)

(72) Inventors: Xiang Feng, Beijing (CN); Xiangdong Wei, Beijing (CN); Jing Liu, Beijing (CN); Yun Qiu, Beijing (CN)

(21) Appl. No.: 14/913,314

(22) PCT Filed: Sep. 17, 2015
(86) PCT No.: PCT/CN2015/089829

§ 371 Date: Feb. 19, 2016

(30) Foreign Application Priority Data
Feb. 6, 2015 (CN) 201510063834.1

(51) Int. Cl. H01L 51/00

(52) U.S. Cl. CPC H01L 51/0028; H01L 51/0096; H01L 51/0012; H01L 51/0007; H01L 51/0566

(57) ABSTRACT

The present disclosure pertains to the technical field of display, which relates to a manufacturing method of a thin film transistor and a thin film transistor, and an array substrate. The manufacturing method of a thin film transistor comprises: forming, above a substrate, patterns comprising different surface energies; coating, above said substrate, a composite solution containing organic semiconductor material and polymer insulating material, and forming a composite film layer; patterning said composite film layer according to the patterns with different surface energies above said substrate, preserving said composite film layer corresponding to the pattern areas with relatively high surface energies; layering said patterned composite film layer by means of an organic solvent steam treatment method; forming two separate metal electrodes at two opposite sides of said patterned composite film layer.

### FIELD

The present disclosure pertains to the technical field of display, specifically to a manufacturing method of a thin film transistor and a thin film transistor, and an array substrate

### BACKGROUND

The organic thin film transistor (OTFT for short) always gets wide attention in academia and industry since it has been found. The manufacture cost thereof is low and can hence satisfy the requirements on flexibility, large area, etc which cannot be satisfied by the silicon semiconductor process. However, patterning of the organic semiconductor material in the organic thin film transistor is always a controversial topic, since it cannot match the existing photolithographic process such that the organic semiconductor material cannot be patterned using conventional photolithography. This results in difficulty in industrialization of the organic thin film transistor.

With constant efforts during the past 10 years in academia, more and more organic thin film transistor patterning processes have been developed, wherein, as for manufacturing the organic thin film transistor using the evaporation plating method, the traditional metal mask evaporation plating process may be employed; as for manufacturing the organic thin film transistor using the solution method, there are a variety of patterning manners, including precursor material photopolymerization method, ink-jet printing method, screen printing method, microcontact method, wetting/dewetting patterning method, etc. All of these methods can directly form a patterned organic semiconductor film layer on the substrate for making an organic semiconductor, but this also causes the problem that film formation between patterns is not synchronous during the process of patterning the organic semiconductor layer, resulting in great difference in film formation between respective patterns on the substrate, thereby influencing the device performance of the organic thin film transistor array. This is not desired in the industrial production.

It can be seen that there is an urgent need currently to solve the technical problem by designing a manufacturing method of a thin film transistor which enables synchronous film formation between the active layer patterns on the substrate.

### SUMMARY

The technical problem to be solved by the present disclosure is to provide, with respect to the above deficiencies existing in the prior arts, a manufacturing method of a thin film transistor and thin film transistor, and an array substrate. The manufacturing method of an organic thin film transistor strictly ensures synchronous film formation between the active layer patterns during the process of patterning the organic semiconductor layer, which eliminates or reduce the difference in film formation between the active layer patterns of respective organic thin film transistors on the substrate.

To solve the above technical problem, a first aspect of the present disclosure proposes a manufacturing method of a thin film transistor. The method may comprise steps of:

forming, above a substrate, patterns comprising different surface energies;

coating, above the substrate, a composite solution containing organic semiconductor material and polymer insulating material, and forming a composite film layer;

patterning the composite film layer according to the patterns with different surface energies above the substrate, preserving the composite film layer corresponding to the pattern areas with relatively high surface energies;

layering the patterned composite film layer by means of an organic solvent steam treatment method;

forming two separate metal electrodes at two opposite sides of the patterned composite film layer.

According to an embodiment, the patterned composite film layer may be layered by the organic solvent steam treatment method into a structure in which an organic semiconductor layer is in an upper part and a polymer insulating layer is in a lower part; at least one end of the metal electrode is located above the organic semiconductor layer.

According to another embodiment, the substrate may be an n-type phosphorous doped substrate whose surface has a silica insulating layer.

According to a further embodiment, forming patterns comprising different surface energies above the substrate may comprise:

forming self-assembled monolayers above the substrate which are connected to the substrate via a covalent bond, wherein the self-assembled unimolecules are unimolecular material with hydrophobic groups;

patterning the self-assembled monolayers to form patterns of a grid structure with different surface energies above the substrate.

In an illustrative embodiment, the method of forming the self-assembled monolayers may comprise: immersing the substrate in a solution containing unimolecular material in the presence of anhydrous argon gas or nitrogen gas, so as to equip the hydrophobic groups of the unimolecular material at the surface of the silica insulating layer.

In an illustrative embodiment, the method of equipping the substrate with hydrophobic groups may comprise: immersing the substrate in a solution containing octyltrichlorosilane, the immersion time ranging from 1.5 to 2.5 h; wherein a solvent for dissolving octyltrichlorosilane is toluene, and the solution has a concentration of 10 mg/ml.

In an illustrative embodiment, the method of patterning the self-assembled monolayers may include any one of UV-OZONE cleaning method of metal mask, photoresist-protecting UV-OZONE cleaning method, photoresist-protecting plasma method, and polydimethylsiloxane microcontact method.

According to yet another embodiment, the solvent in the composite solution is a solvent capable of dissolving the organic semiconductor material and the polymer insulating material simultaneously, the organic semiconductor material may be crystallizable micromolecule semiconductor material. Specifically, the organic semiconductor material may include any one of TES-ADT, TIPS_PEN, BTBT, DATT and DNTT; the polymer insulating material may include polymethylmethacrylate or polystyrene.

According to an additional embodiment, the composite solution may form the composite film layer by a spin-coating method, wherein,

the solvent is a low boiling point organic solvent whose boiling point temperature ranges from 60 to 150° C., the spin-coating speed of the composite solution containing the low boiling point organic solvent is 3500 rpm, and the rotation time ranges from 15 to 20 s;

or, the solvent is a high boiling point organic solvent whose boiling point temperature ranges from 150 to 250° C., the spin-coating speed of the composite solution containing the high boiling point organic solvent is 5000 rpm, and the rotation time ranges from 15 to 20 s.

In an illustrative embodiment, the low boiling point organic solvent may be any one of chloroform, tetrahydrofuran, toluene, o-xylene, p-xylene, m-xylene and chlorobenzene or a combination of any several ones;

the high boiling point organic solvent may be any one of 1,2 dichlorobenzene, 1,2,4 trichlorobenzene and dimethyl sulfoxide or a combination of any several ones.

According to an embodiment, in the composite solution, a mass ratio of the organic semiconductor material may be smaller than or equal to a mass ratio of the polymer insulating material. Specifically, a mass ratio of the organic semiconductor material to the polymer insulating material may be in the range of 1:99 to 1:4.

In an illustrative embodiment, when the mass ratio of the organic semiconductor material to the polymer insulating material is 1:4, the composite solution has a concentration of 12.5 mg/ml.

According to another embodiment, patterning of the composite film layer may be effected by removing the composite film layer above and corresponding to the pattern areas with relatively low surface energies, comprising: attach an adhesive tap with viscosity onto the composite film layer, physically stripping the composite film layer above and corresponding to the pattern areas with relatively low surface energies by means of the adhesive tape.

In an illustrative embodiment, before patterning the composite film layer, it may further comprise:

preparing a sacrificial layer above the composite film layer;

attach an adhesive tape with viscosity onto the sacrificial layer, physically stripping the sacrificial layer by means of the adhesive tape while stripping the composite film layer above the pattern areas with relatively low surface energies.

In an illustrative embodiment, the sacrificial layer may be formed by spin-coating a solution; the solution comprises polymethylmethacrylate and/or polystyrene; the solvent for dissolving polymethylmethacrylate and/or polystyrene is n-butyl acetate.

In an illustrative embodiment, the solution may comprise polymethylmethacrylate having a molar mass of 120 kg/mol and/or polystyrene having a molar mass of 200 kg/mol.

In an illustrative embodiment, the solution may have a concentration in the range of 70 to 90 mg/ml, the spin-coating speed ranges from 1800 to 2200 rpm, the rotation time ranges from 50 to 70 s, and the sacrificial layer has a thickness in the range of 400 to 600 nm.

In an illustrative embodiment, the solution may have a concentration of 80 mg/ml, the spin-coating speed is 2000 rpm, the rotation time is 60 s, and the sacrificial layer has a thickness of 500 nm.

According to an embodiment, after forming the sacrificial layer, it may further comprise a step of thermal curing of the sacrificial layer, the temperature for thermal curing of the sacrificial layer ranges from 70 to 90° C., and the time of thermal curing ranges from 20 to 40 min.

According to another embodiment, the temperature for thermal curing of the sacrificial layer is 80° C.; the time of thermal curing is 30 min.

According to the embodiment, layering the patterned composite film layer by means of the organic solvent steam treatment method may comprise:

placing the substrate in a sealed environment containing an organic solvent;

vacuumizing the sealed environment such that the organic solvent is vaporized to thereby form a sealed steam environment;

the organic semiconductor material moving to the top of the patterned composite film layer and crystalline grains becoming larger during the upward movement, the polymer insulating material moving to the bottom of the patterned composite film layer.

In an illustrative embodiment, the organic solvent may be any one of 1,2-dichloroethane, toluene, chlorobenzene and chloroform.

According to a further embodiment, before patterning the composite film layer, it may further comprise a step of thermal curing of the composite film layer, the temperature for thermal curing of the composite film layer ranges from 140 to 160° C., and the time for thermal curing ranges from 8 to 12 min.

In an illustrative embodiment, the temperature for thermal curing of the composite film layer may be 150° C., the time for thermal curing is 10 min.

According to yet another embodiment, the two separate metal electrodes may be a source and a drain, the metal electrodes employ gold material and are formed by metal mask evaporation plating, and the separate area between the source and the drain forms a channel area.

In an illustrative embodiment, the source and the drain may have a thickness in the range of 60 to 100 nm, the channel area has a length in the range of 80 to 100 μm and a width in the range of 700 to 900 μm.

A second aspect of the present disclosure provides a thin film transistor, which is formed using the above manufacturing method of a thin film transistor.

A third aspect of the present disclosure provides an array substrate which may comprise the above thin film transistor.

The beneficial effects of the present disclosure include: the manufacturing method of a thin film transistor, during the process of patterning the organic semiconductor layer, strictly ensures synchronous film formation between the active layer patterns, which eliminates or reduces the difference in film formation between the active layer patterns of respective organic thin film transistors on the substrate, thereby ensuring the device performance of the organic thin film transistor.

### BRIEF DESCRIPTION OF DRAWINGS

FIG. 1 is a flow chart of a manufacturing method of a thin film transistor according to the embodiments of the present disclosure.

FIG. 2 is a schematic diagram of forming patterns with different surface energies above the substrate according to the embodiments of the present disclosure.

FIGS. 3A, 3B are schematic diagrams of forming a composite film layer according to the embodiments of the present disclosure.

FIGS. 4A, 4B are schematic diagrams of removing the composite film layer above and corresponding to the pattern areas with relatively low surface energies.

FIGS. 5A, 5B are schematic diagrams of layering the composite film layer by means of an organic solvent steam treatment method according to the embodiments of the present disclosure.

FIG. 6 is a schematic diagram of organic thin film transistors formed above the substrate according to the embodiments of the present disclosure.

FIG. 7 is a structural schematic diagram of a single organic thin film transistor according to the embodiments of the present disclosure.

In the figures,
1—substrate;
2—patterned self-assembled monolayer;
30—composite solution; 31—composite film layer; 32—patterned composite film layer; 33—polymer insulating layer; 34—organic semiconductor layer;
4—sacrificial layer;
5—adhesive tape;
61—source; 62—drain;
7—organic solvent steam environment.

### DETAILED DESCRIPTION

To enable those skilled in the art to better understand the technical solution of the present disclosure, the manufacturing method of a thin film transistor and the thin film transistor and the array substrate of the present disclosure are further described in detail as follows in combination with the figures and specific implementations.

The present disclosure provides a manufacturing method of a thin film transistor and a thin film transistor correspondingly formed using the manufacturing method of a thin film transistor. The thin film transistor is an organic thin film transistor. The manufacturing method of a thin film transistor comprises by employing a silicon wafer with a silica insulating layer as a substrate, using the silicon wafer as a gate of the organic thin film transistor device, the silica insulating layer of the silicon wafer and a polymer insulating layer formed by polymer insulating material as a gate insulating layer of the organic thin film transistor device, and an organic semiconductor layer as an active layer of the organic thin film transistor device, and subsequently forming a source and a drain of the organic thin film transistor device. Film formation between the active layer patterns of the organic thin film transistor devices on the substrate are synchronous, thus the difference in film formation between the respective active layer patterns on the substrate is eliminated or reduced, thereby ensuring the device performance of the organic thin film transistor array.

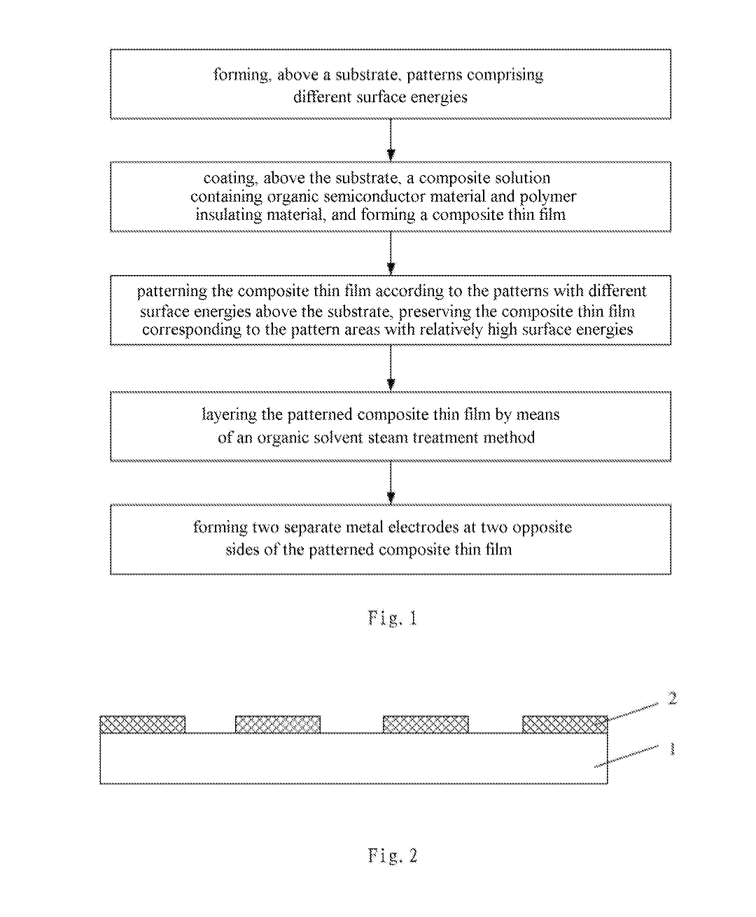

As shown in FIG. 1, the manufacturing method specifically comprises the following steps:

At step S1, patterns comprising different surface energies are formed above a substrate.

FIG. 2 shows a schematic diagram of forming patterns comprising different surface energies above a substrate, wherein the different surface energies are decided by patterned self-assembled monolayers 2 (hereinafter referred to as SAM for short), wherein the substrate 1 is an n-type phosphorus doped substrate (not shown in FIG. 2) whose surface has a silica insulating layer. The thickness of the silica insulating layer ranges from 200 to 400 nm.

In this step, forming patterns comprising different surface energies above the substrate 1 comprises:

At step S11, a self-assembled monolayer is formed above the substrate 1 which is connected to the substrate 1 via a covalent bond, wherein the self-assembled unimolecules are unimolecules with hydrophobic groups. The self-assembled unimolecules are a surfactant, which play the role of assisting in the formation of an active layer of the thin film transistor which is to be formed subsequently.

The method of forming the self-assembled monolayers comprises: immersing the substrate 1 in a solution containing unimolecular material in the presence of anhydrous argon gas (or nitrogen gas) such that the hydrophobic groups of the unimolecular material are equipped at the surface of the silica insulating layer. Specifically, the method of equipping the substrate 1 with hydrophobic groups comprises: immersing the clean substrate 1 that has been subjected to hydroxylation into a solution containing octyltrichlorosilane (OTS), the immersion time ranging from 1.5 to 2.5 h; wherein the solvent for dissolving octyltrichlorosilane is toluene, and the concentration of the solution is 10 mg/ml.

At step S12, the self-assembled monolayers are patterned to form on the substrate 1 patterns of a grid structure with different surface energies, i.e., patterned self-assembled monolayers 2. The method of patterning the self-assembled monolayers includes any one of UV-OZONE cleaning method of metal mask, photoresist-protecting UV-OZONE cleaning method, photoresist-protecting plasma method, and polydimethylsiloxane (PDMS) microcontact method. Any one of the above methods can be selected as the patterning method according to process requirements, which is not defined here.

At the upper surface of the substrate 1, since the SAM layer is a monolayer with hydrophobic groups, the surface energies of the areas on the substrate 1 which are provided with the SAM layer are relatively low, while the surface energies of the areas on the substrate 1 which are not provided with the SAM layer are relatively high. That is, the areas on the substrate 1 which are equipped with a self-assembled monolayer have a relatively low surface energy, poor hydrophilicity, strong hydrophobicity and small adhesive force; the areas on the substrate 1 which are not provided with the self-assembled monolayer have a relatively high surface energy, strong hydrophilicity, poor hydrophobicity and large adhesive force.

It should be understood that the self-assembled monolayers here employ octyltrichlorosilane in order to enable the composite solution in the subsequent steps to form a film on the self-assembled monolayers, while octadecyltrichlorosilane and perfluorosilane are not recommended for use. Meanwhile, the manufacturing method is not limited to metal mask and UV-OZONE method as long as alternating micropatterns with relatively high surface energy/relatively low surface energy can be obtained on the substrate 1. It is also possible to employ a photoresist protection method, a PDMS microcontact method, etc, which is not defined here.

At step S2, a composite solution 30 containing an organic semiconductor material and a polymer insulating material is coated above the substrate 1 to form a composite film layer 31.

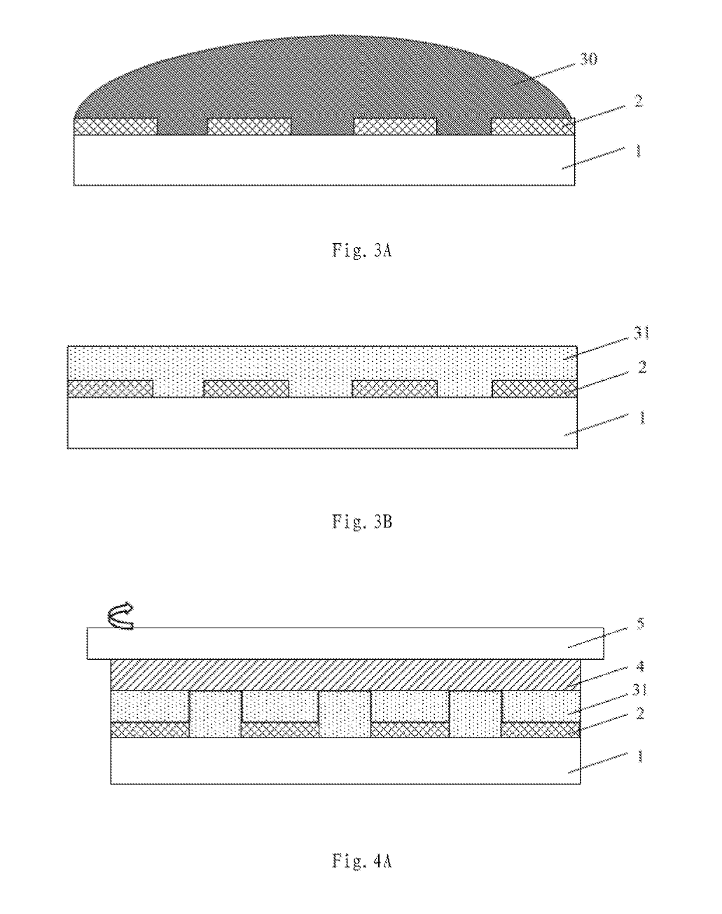

As shown in FIG. 3A, in this step, the solvent in the composite solution 30 is a solvent capable of dissolving the organic semiconductor material and the polymer insulating material simultaneously. The organic semiconductor material includes any one of TES-ADT, TIPS_PEN, BTBT, DATT and DNTT. The polymer insulating material includes polymethylmethacrylate (PMMA) or polystyrene (PS). According to process requirements, any one of the above materials can be selected as the organic semiconductor material and the polymer insulating material, or other materials having the same property as the above materials can be selected, which is not defined here.

As an example, the organic semiconductor material is, for example, crystallizable micromolecule semiconductor material, such as TES-ADT, TIPS_PEN, BTBT, DATT, DNTT, etc. The names and structural formulas of TES-ADT, TIPS_PEN, BTBT, DATT and DNTT are set forth in detail as follows.

TES-ADT is 5,11-Bis (triethylsilylethynyl) anthradithiophene, and its structural formula is shown as follows:

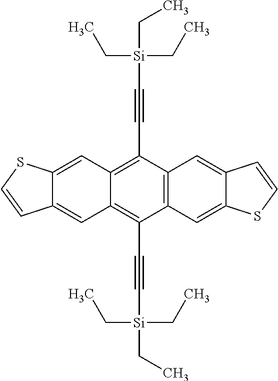 [SMILES: CC[Si](C#Cc1c2cc3ccsc3cc2c(C#C[Si](CC)(CC)CC)c2cc3ccsc3cc12)(CC)CC]

TIPS_PEN is 6,13-Bis (triisopropylsilylethynyl) pentacene, and its structural formula is shown as follows:

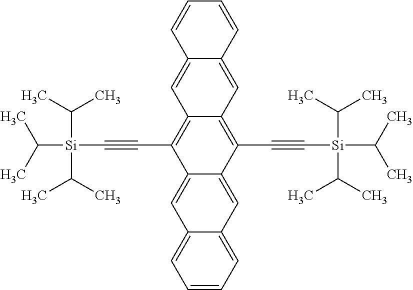 [SMILES: CC(C)[Si](C#Cc1c2cc3ccccc3cc2c(C#C[Si](C(C)C)(C(C)C)C(C)C)c2cc3ccccc3cc12)(C(C)C)C(C)C]

BTBT is benzothienobenzothiophene. The derivatives of the molecule are BTBT-like molecules and derivative molecule material thereof. The general formula of the derivative molecules thereof is Cₙ-BTBT, wherein 3≦n≦12. For example, C₈—BTBT is one of the derivatives, the name thereof is 2,7-Dioctyl [1] benzothieno [3,2-b] [1] benzothiophene, and the structural formula thereof is shown as follows:

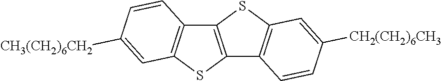

DATT is dianthra [2,3-b:2′,3′-f] thieno [3,2-b] thiophene, and its structural formula is shown as follows:

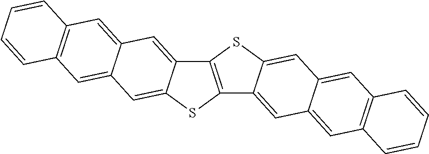 [SMILES: c1ccc2cc3cc4c(cc3cc2c1)sc1c2cc3cc5ccccc5cc3cc2sc41]

DNTT is Dinaphtho [2,3-b:2′,3′-f] thieno [3,2-b] thiophene, and its structural formula is shown as follows:

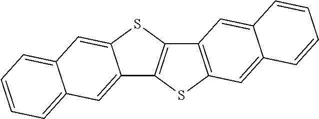 [SMILES: c1ccc2cc3c(cc2c1)sc1c2cc4ccccc4cc2sc31]

The general formula of the derivative molecules of DNTT is Cₙ-DNTT, wherein 3≦n≦12. For example, C₁₀-DNTT is one of the derivatives, the name thereof is 2,9-didecyldi-naphtho [2,3-b:2′,3′-f] thieno [3,2-b] thiophene (C₁₀-DNTT), and the structural formula thereof is shown as follows:

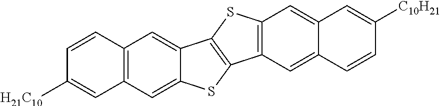

As an example, traditional polymer material may be used as the polymer insulating material, such as polymethylmethacrylate (PMMA) having a molar mass of 996 kg/mol, polystyrene (PS) having a molar mass of 200 kg/mol, and so on.

It should be understood that as regards the mass ratio relationship between the organic semiconductor material and the polymer insulating material in the composite solution 30, it is desired to make the polymer insulating material excessive in amount, i.e., the mass ratio of the organic semiconductor material is smaller than or equal to that of the polymer insulating material so as to enable coating of the organic semiconductor material micromolecules by the polymer insulating layer during the spin-coating process. In an example, the mass ratio of the organic semiconductor material to the polymer insulating material is 1:99 to 1:4, i.e., 1 part by mass of the organic semiconductor material can be compounded with 4-99 parts by mass of the polymer insulating layer. According to process requirements, the mass ratio of the organic semiconductor material to the polymer insulating material may be selected as any one of the above mass ratios, which is not defined here. When the mass ratio of the organic semiconductor material to the polymer insulating material is 1:4, the concentration of the composite solution 30 is 12.5 mg/ml.

The composite solution 30 forms the composite film layer 31 by spin-coating method, and the solvent is an organic solvent whose boiling point temperature ranges from 60 to 250° C., wherein,

the solvent is a low boiling point organic solvent whose boiling point temperature ranges from 60 to 150° C., the spin-coating speed of the composite solution 30 containing the low boiling point organic solvent is ≧3500 rpm, and the rotation time ranges from 15 to 20 s. The low boiling point organic solvent is any one of chloroform, tetrahydrofuran, toluene, o-xylene, p-xylene, m-xylene and chlorobenzene or a combination of any several ones;

or, the solvent is a high boiling point organic solvent whose boiling point temperature ranges from 150 to 250° C., the spin-coating speed of the composite solution 30 containing the high boiling point organic solvent is ≧5000 rpm, and the rotation time ranges from 15 to 20 s. The high boiling point organic solvent is any one of 1,2 dichlorobenzene, 1,2,4 trichlorobenzene and dimethyl sulfoxide or a combination of any several ones.

It should be understood that the solvent may be an organic solvent which has a low boiling point and is capable of dissolving the two component materials of the organic semiconductor material and the polymer insulating material. With regard to selection of the speed for manufacture, a high speed can be considered so as to enable the composite solution 30 to rapidly form a film to form the composite film layer 31, while not leaving sufficient time for phase separation between the organic semiconductor material and the polymer insulating material, and preventing the organic semiconductor material and the polymer insulating material from forming a layer division with a clear interface.

When the solvent with high boiling point is selected, the rotation time of the mixed solution may be the same as the rotation time of the mixed solution that selects the solvent with low boiling point. At that time, since the spin-coating speed thereof is higher than that of the mixed solution of the solvent with low boiling point, the mixed solution has formed and cured the composite film layer during the spin-coating process, which can also prevent sufficient phase separation between the organic semiconductor material and the polymer insulating material.

According to process requirements, the solvent can be selected as any one of the above materials, and corresponding spin-coating speed and rotation time are selected to form the composite film layer 31 with different thicknesses, which is not defined here. For example, when the mass ratio of the organic semiconductor material to the polymer insulating material is 1:4, and the concentration of the composite solution 30 is 12.5 mg/ml, the thickness of the prepared composite film layer 31 is in the range of 50 to 100 nm.

After completion of the above spin-coating process, the organic semiconductor material is partially crystallized, but there is no clear interface between the organic semiconductor material and the polymer insulating material.

To obtain optimal organic semiconductor layer 34 and polymer insulating layer 33 having a clear layered interface in subsequent steps, a step of thermal curing of the composite film layer 31 is further comprised prior to patterning the composite film layer 31. The temperature for thermal curing of the composite film layer 31 is in the range of 140 to 160° C., and the time for thermal curing ranges from 8 to 12 min.

As shown in FIG. 3A, the composite solution 30 is spin-coated onto the pretreated substrate 1 and the patterned self-assembled monolayers 2. As shown in FIG. 3B, after the process of spin-coating and curing, the composite solution 30 forms the composite film layer 31 which is subsequently subjected to thermal curing treatment on a hot stage at 150° C. to enhance the connection between the composite film layer 31 and the substrate 1.

At step S3, the composite film layer 31 is patterned according to the patterns with different surface energies above the substrate 1 to preserve the composite film layer 31 corresponding to the pattern areas with relatively high surface energies.

In this step, patterning of the composite film layer 31 is effected by removing the composite film layer 31 above and corresponding to the pattern areas with relatively low surface energies. In the present embodiment, different physical stripping manners can be used to remove the composite film layer 31 above and corresponding to the pattern areas with relatively low surface energies, while preserving the composite film layer 31 corresponding to the pattern areas with relatively high surface energies so as to form a patterned composite film layer 32. It should be noted that the values of the relatively high surface energies and the relatively low surface energies can be set based on needs.

A simple manner of removal is: attach an adhesive tap with viscosity onto the composite film layer 31, physically stripping the composite film layer 31 above and corresponding to the pattern areas with relatively low surface energies by means of the adhesive tape to form the patterned composite film layer 32. For example, a 3M adhesive tape can be used to carry out the physical stripping. Since the adhesive force between the composite film layer 31 and the areas on the substrate 1 which are not provided with the SAM layer is very large (very strong), it is not easy to strip. However, the adhesive force between the composite film layer 31 and the areas on the substrate 1 which are provided with the SAM layer is very small (very weak), thus it is easy to strip to obtain the patterned composite film layer 32. In this manner, since the adhesive tape with viscosity usually contains a polymer, the polymer may have impact on the organic semiconductor material in the composite film layer 31.

Another alternative manner of removing the composite film layer 31 above and corresponding to the pattern areas with relatively low surface energies is: forming a sacrificial layer above the composite film layer 31, then simultaneously removing the sacrificial layer and the composite film layer 31 above and corresponding to the pattern areas with relatively low surface energies by means of the adhesive tape. Namely, before removing the composite film layer 31 above and corresponding to the pattern areas with relatively low surface energies, the following steps are further comprised:

At step S31, a sacrificial layer 4 is prepared above the composite film layer 31.

The sacrificial layer 4 is formed by spin-coating a solution. The solution comprises polymethylmethacrylate (PMMA) and/or polystyrene (PS). The solvent for dissolving polymethylmethacrylate (PMMA) and/or polystyrene (PS) is n-butyl acetate. According to process requirements, the substances comprised in the solution for preparing the sacrificial layer 4 may be selected from any one or two of the above materials, or other materials having the same property as the above materials can be selected, which is not defined here.

The solution therein may comprise polymethylmethacrylate (PMMA) having a molar mass of 120 kg/mol or polystyrene (PS) having a molar mass of 200 kg/mol, which may also comprise polymethylmethacrylate (PMMA) having a molar mass of 120 kg/mol and polystyrene (PS) having a molar mass of 200 kg/mol, simultaneously; wherein the n-butyl acetate solvent would not have impact on the organic semiconductor material in the composite film layer 31 and can reduce dissolution of the composite film layer 31 by the solvent at the time of preparing the sacrificial layer 4, ensuring the performance of the active layer to be subsequently formed.

In an example, the concentration of the solution ranges from 70 to 90 mg/ml, the spin-coating speed ranges from 1800 to 2200 rpm, the rotation time ranges from 50 to 70 s, and the thickness of the sacrificial layer 4 ranges from 400 to 600 nm. Specifically, the prepared concentration of the solution may be 80 mg/ml, the spin-coating speed is 200 rpm, the rotation time is 60 s, and the prepared sacrificial layer 4 has a thickness of about 500 nm.

In order to obtain an optimal quality of the sacrificial layer 4, it is possible to make the solvent volatilized sufficiently by means of thermal curing, and at the same time enhance the adhesive property between the sacrificial layer 4 and the composite film layer 31. Namely, a step of thermal curing of the sacrificial layer 4 is further comprised after the sacrificial layer 4 has been formed. The temperature for thermal curing of the sacrificial layer 4 ranges from 70 to 90° C., and the time of thermal curing ranges from 20 to 40 min. Specifically, the temperature for thermal curing can be 80° C. and the time of thermal curing is 30 min to facilitate planarization of the sacrificial layer 4 and connection thereof to the composite film layer.

At step S32, the adhesive tape 5 with viscosity is attached onto the sacrificial layer 4, and the sacrificial layer 4 is physically stripped by the adhesive tape 5 simultaneously with stripping the composite film layer 31 above the pattern areas with relatively low surface energies.

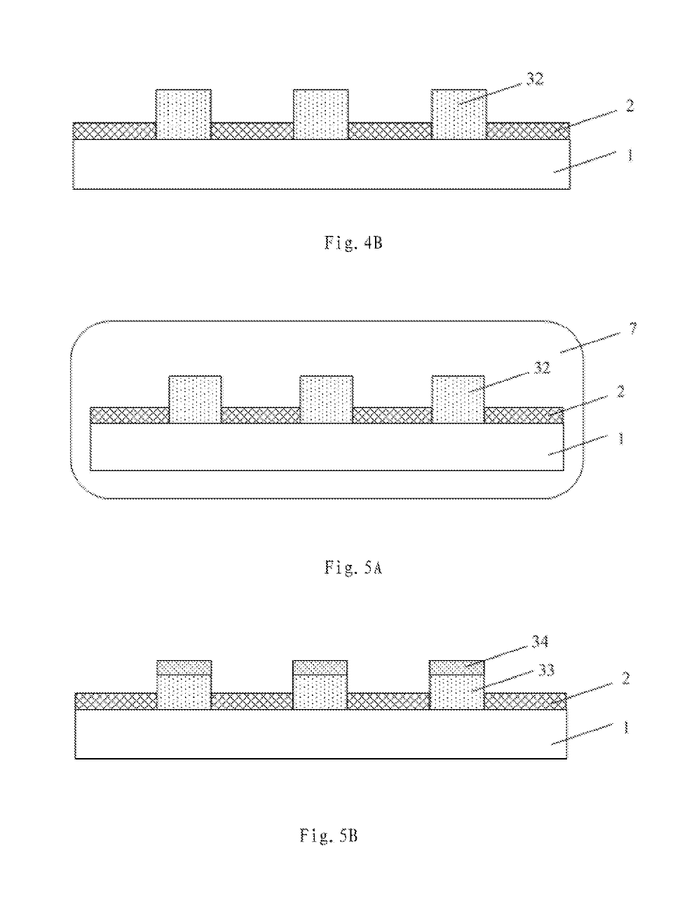

For example, the 3M adhesive tap 5 is used to carry out the physical stripping. Since the adhesive force between the composite film layer 31 and the areas on the substrate 1 which are not provided with the SAM layer is very large (very strong), it is not easy to strip. However, the adhesive force between the composite film layer 31 and the areas on the substrate 1 which are provided with the SAM layer is very small (very weak), thus it is easy to strip. As shown in FIG. 4A, the adhesive tape 5 is torn off along the arrow direction, and the composite film layer 31 would be stripped off along the section of the black line to obtain the patterned composite film layer 32 as shown in FIG. 4B.

It should be noted that in the step of removing the composite film layer 31 above and corresponding to the pattern areas with relatively low surface energies, since the phase separation between the organic semiconductor material and the polymer insulating material in the composite film layer 31 at that time is not performed thoroughly, the composite film layer 31 can be regarded as a whole. During the stripping process, the two components of the composite film layer 31 would not be separated accordingly.

At step S4, the composite film layer 31 is layered by organic solvent steam treatment method.

In this step, movement occurs in the interior of the system for forming the patterned composite film layer 32 by means of the organic solvent steam treatment method such that the organic semiconductor material and the polymer insulating material form a structure in which the organic semiconductor layer 34 is in the upper part and the polymer insulating layer 33 is in the lower part.

Specifically, layering the patterned composite film layer 32 by means of the organic solvent steam treatment method comprises:

At step S41, the substrate 1 is placed in a sealed environment containing an organic solvent. Particularly, the organic solvent is any one of 1,2-dichloroethane, toluene, chlorobenzene and chloroform. According to process requirements, the organic solvent may be selected as any one of the above materials, which is not defined here.

In this step, the patterned composite film layer 32 as shown in FIG. 4B is placed in the sealed environment to create an organic solvent steam environment 7, as shown in FIG. 5A. The sealed environment here may be a glass container that can be vacuumized, inside which the organic solvent is placed. The organic solvent needs to meet the requirement of dissolving the organic semiconductor material and the polymer insulating material simultaneously. A selectable organic solvent is 1,2-dichloroethane, while commonly used organic solvents such as toluene, chlorobenzene, chloroform, etc can also be employed.

At step S42, the sealed environment is vacuumized such that the organic solvent is vaporized to thereby form a sealed steam environment.

In this step, the sealed environment is vacuumized to create the organic solvent steam environment 7, i.e., vaporizing the organic solvent in a vacuum environment so as to provide a steam atmosphere in the glass container. The sealed environment filled with the organic solvent as provided here enables the organic solvent to impregnate into the patterned composite film layer 32 to accomplish steam annealing.

At step S43, the organic semiconductor material slowly moves to the top of the patterned composite film layer 32 and crystalline grains become larger during the upward movement. The polymer insulating material moves to the bottom of the patterned composite film layer 32. During this process, the phase separation between the organic semiconductor layer phase and the polymer insulating layer phase would be more thorough than that before the organic solvent steam treatment.

During the process of forming the patterned composite film layer 32 in FIG. 4B, the phase separation between the organic semiconductor material and the polymer insulating material in the patterned composite film layer 32 is not performed thoroughly. The steam of the organic solvent is enabled to impregnate into the patterned composite film layer 32 by means of steam annealing, such that the organic semiconductor material moves to the top of the patterned composite film layer 32 and the polymer insulating material moves to the bottom of the patterned composite film layer 32 to facilitate the phase separation of the composite material film layer, so that the patterned composite film layer 32 is layered to form a structure in FIG. 5B in which the organic semiconductor layer 34 is in the upper part and the polymer insulating layer 33 is in the lower part. Meanwhile, the organic semiconductor material is crystallized rapidly during the upward movement, as a result the sizes of grains become larger, such that the organic semiconductor layer 34 has better film forming performance in the patterned composite film layer 32.

The double-layer structure in which the organic semiconductor layer 34 is in the upper part and the polymer insulating layer 33 is in the lower part is accomplished through the above steps, i.e., by combining the physical stripping process with the steam annealing process, first physically stripping to obtain the patterned composite film layer 32, then facilitating further phase separation in the patterned composite film layer 32 by means of steam annealing.

At step S5, two separate metal electrodes are formed at two opposite sides of the patterned composite film layer 32.

In this step, in the two separate metal electrodes, one end of either metal electrode is located above the organic semiconductor layer 34 and the other end is located above the pattern area with a relatively low surface energy. The above position of the metal electrode is only illustrative. According to the structure of the thin film transistor, it is possible that at least one end of the metal electrode is located on the organic semiconductor layer, while the other end may be located above the pattern area with a relatively low surface energy, or located above other layer structures corresponding to the pattern area with a relatively low surface energy, which is not defined here. During the practical preparation, it is possible to adjust the layer structures above and corresponding to the pattern areas with relatively low surface energies according to the needs of the thin film transistor structure.

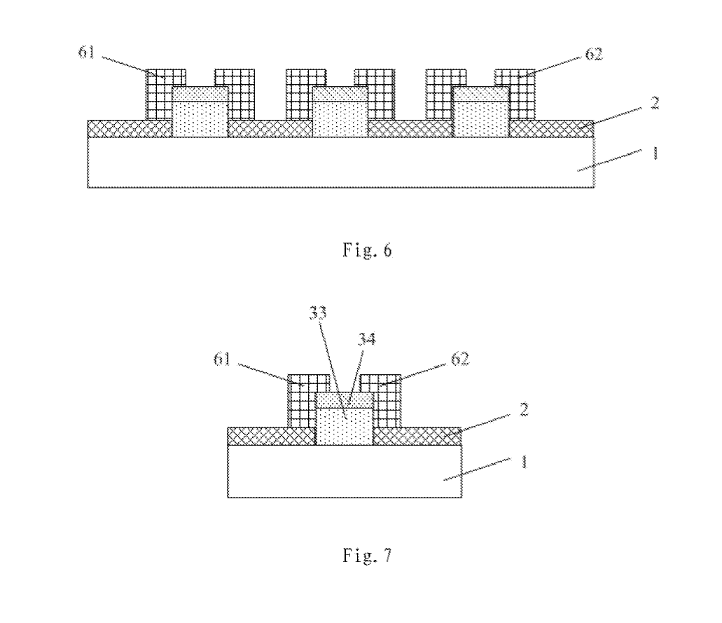

As shown in FIG. 6, the two separate metal electrodes are a source 61 and a drain 62. The source 61 and the drain 62 both employ gold material and are formed by metal mask evaporation plating. The separate area between the source 61 and the drain 62 forms a channel area. In an example, the source 61 and the drain 62 have a thickness in the range of 60 to 100 nm, and the channel area has a length in the range of 80 to 100 μm and a width in the range of 700 to 900 μm. Specifically, the width of the channel can be 800 μm.

FIG. 7 is a structural schematic diagram of a single organic thin film transistor formed by the above manufacturing method of a thin film transistor. The thin film transistor employs a silicon wafer with a silica insulating layer as the substrate 1. Since the silicon wafer is conductive, the silicon wafer can be directly used as the gate of the organic thin film transistor device. The patterned self-assembled monolayers, physical stripping method and organic solvent steam treatment method are employed to accomplish the preparation of the organic semiconductor layer 34 and the polymer insulating layer 33. At that time, the silica insulating layer of the silicon wafer and the polymer insulating layer 33 are used as the gate insulating layer of the organic thin film transistor device and the organic semiconductor layer 34 is used as the active layer of the organic thin film transistor device. Subsequently, two separate metal electrodes as well as channels are formed by metal mask evaporation plating above the patterned organic semiconductor layer 34 and the polymer insulating layer 33, thereby completing the organic thin film transistor whose bottom gate has top contacts (in contact with the active layer).

In the manufacturing method of an organic thin film transistor, during the process of patterning the organic semiconductor layer, synchronous film formation between the active layer patterns is strictly ensured, which eliminates or reduces the difference in film formation between the active layer patterns of respective organic thin film transistors on the substrate, thereby ensuring the device performance of the organic thin film transistor.

The embodiments of the present disclosure further provides an array substrate comprising the above organic thin film transistor.

A plurality of organic thin film transistors formed using the manufacturing method of an organic thin film transistor according to above embodiment can be arranged in the array substrate. The plurality of organic thin film transistors are arranged in an array and gate lines and data lines which are crisscrossed are further formed. Thereafter, the pixel electrode, etc can continue to be formed using the existing techniques so as to form a liquid crystal array substrate, or, the OLED device is manufactured to form an OLED array substrate.

At the time of forming a plurality of organic thin film transistors in the array substrate, the patterns of the patterned self-assembled monolayers are complementary to the patterns of the gates of the organic thin film transistors.

The array substrate can be manufactured to form an OLED display panel, a twisted nematic (TN) type liquid crystal display panel, a vertical alignment (VA) type liquid crystal display panel, and an advanced super dimension switch (ADS) type liquid crystal display panel, which is not defined here. Accordingly, it can further form any product or component having display function such as liquid crystal panel, electronic paper, OLED panel, mobile phone, tablet computer, television, display, notebook computer, digital frame, navigator, and so on.

The manufacturing method of a thin film transistor as provided by the embodiments of the present disclosure achieves the technical effect of enabling patterning and phase separation of the organic semiconductor/polymer insulating composite material by means of the technical measure of combining the physical stripping process and the steam annealing process, i.e., first physically stripping to obtain the patterned composite film layer, then facilitating phase separation between the organic semiconductor material and the polymer insulating material in the composite film layer by means of steam annealing, completing a double-layer structure in which the organic semiconductor layer is in the upper part and the polymer insulating layer is in the lower part. Therefore, it further strictly ensures synchronous film formation between the active layer patterns of different organic thin film transistors in the organic thin film transistor array after patterning while forming the structure of the organic thin film transistor device, solving the technical problem of synchronization of the organic semiconductor layer patterns.

The organic thin film transistor formed by the manufacturing method of a thin film transistor has better performance such that the array substrate comprising the organic thin film transistor has better display performance.

It can be understood that the above embodiments are illustrative embodiments used only for explaining the principle of the present disclosure, but the present disclosure is not limited to that. Those ordinarily skilled in the art can make various variations and improvements without departing from the spirit and essence of the present disclosure. These variations and improvements are also regarded as the protection scope of the present disclosure.

1-33. (canceled)

34. A manufacturing method of a thin film transistor, comprising the steps of:
forming, above a substrate, patterns comprising different surface energies;
coating, above said substrate, a composite solution containing organic semiconductor material and polymer insulating material, and forming a composite film layer;
patterning said composite film layer according to the patterns with different surface energies above said substrate, preserving said composite film layer corresponding to the pattern areas with relatively high surface energies;
layering said patterned composite film layer by means of an organic solvent steam treatment method;
forming two separate metal electrodes at two opposite sides of said patterned composite film layer.

35. The manufacturing method according to claim 34, wherein said patterned composite film layer is layered by the organic solvent steam treatment method into a structure in which an organic semiconductor layer is in an upper part and a polymer insulating layer is in a lower part; at least one end of said metal electrode being located above said organic semiconductor layer.

36. The manufacturing method according to claim 34, wherein said substrate is an n-type phosphorous doped substrate whose surface has a silica insulating layer.

37. The manufacturing method according to claim 36, wherein forming patterns comprising different surface energies above said substrate comprises:
forming self-assembled monolayers above said substrate which are connected to said substrate via a covalent bond, wherein the self-assembled unimolecules are unimolecular material with hydrophobic groups;
patterning said self-assembled monolayers to form patterns of a grid structure with different surface energies above said substrate.

38. The manufacturing method according to claim 37, wherein the method of forming said self-assembled monolayers comprises: immersing said substrate in a solution containing unimolecular material in the presence of anhydrous argon gas or nitrogen gas, so as to equip the hydrophobic groups of said unimolecular material at the surface of said silica insulating layer.

39. The manufacturing method according to claim 38, wherein the method of equipping said substrate with hydrophobic groups comprises: immersing said substrate in a solution containing octyltrichlorosilane, the immersion time ranging from 1.5 to 2.5 h; wherein a solvent for dissolving octyltrichlorosilane is toluene, and the solution has a concentration of 10 mg/ml.

40. The manufacturing method according to claim 34, wherein the solvent in said composite solution is a solvent capable of dissolving said organic semiconductor material and said polymer insulating material simultaneously, said organic semiconductor material is crystallizable micromolecule semiconductor material.

41. The manufacturing method according to claim 40, wherein said composite solution forms said composite film layer by a spin-coating method, and wherein,
said solvent is a low boiling point organic solvent whose boiling point temperature ranges from 60 to 150° C., the spin-coating speed of said composite solution containing said low boiling point organic solvent is 3500 rpm, and the rotation time ranges from 15 to 20 s;
or, said solvent is a high boiling point organic solvent whose boiling point temperature ranges from 150 to 250° C., the spin-coating speed of said composite solution containing the high boiling point organic solvent is 5000 rpm, and the rotation time ranges from 15 to 20 s.

42. The manufacturing method according to claim 34, wherein, in said composite solution, a mass ratio of said organic semiconductor material is smaller than or equal to a mass ratio of said polymer insulating material.

43. The manufacturing method according to claim 34, wherein patterning of said composite film layer is effected by removing said composite film layer above and corresponding to the pattern areas with relatively low surface energies, comprising: attach an adhesive tap with viscosity onto said composite film layer, physically stripping said composite film layer above and corresponding to the pattern areas with relatively low surface energies by means of said adhesive tape.

44. The manufacturing method according to claim 34, wherein, before patterning said composite film layer, it further comprises:
preparing a sacrificial layer above said composite film layer;
attaching an adhesive tape with viscosity onto said sacrificial layer, physically stripping said sacrificial layer by means of said adhesive tape while stripping said composite film layer above the pattern areas with relatively low surface energies.

45. The manufacturing method according to claim 44, wherein said sacrificial layer is formed by spin-coating a solution; the solution comprises polymethylmethacrylate and/or polystyrene; the solvent for dissolving polymethylmethacrylate and/or polystyrene is n-butyl acetate.

46. The manufacturing method according to claim 45, wherein said solution comprises polymethylmethacrylate having a molar mass of 120 kg/mol and/or polystyrene having a molar mass of 200 kg/mol.

47. The manufacturing method according to claim 45, wherein, after forming said sacrificial layer, it further comprises a step of thermal curing of said sacrificial layer, the temperature for thermal curing of said sacrificial layer ranging from 70 to 90° C., the time of thermal curing ranging from 20 to 40 min.

48. The manufacturing method according to claim 34, wherein layering said patterned composite film layer by means of the organic solvent steam treatment method comprises:
placing said substrate in a sealed environment containing an organic solvent;
vacuumizing the sealed environment such that said organic solvent is vaporized to thereby form a sealed steam environment;
said organic semiconductor material moving to the top of said patterned composite film layer and crystalline grains becoming larger during the upward movement, said polymer insulating material moving to the bottom of said patterned composite film layer.

49. The manufacturing method according to claim 34, wherein, before patterning said composite film layer, it further comprises a step of thermal curing of said composite film layer, the temperature for thermal curing of said composite film layer ranging from 140 to 160° C., the time for thermal curing ranging from 8 to 12 min.

50. The manufacturing method according to claim 34, wherein said two separate metal electrodes are a source and a drain, said metal electrodes employing gold material and being formed by metal mask evaporation plating, the separate area between said source and said drain forming a channel area.

51. The manufacturing method according to claim 50, wherein said source and said drain have a thickness in the range of 60 to 100 nm, said channel area has a length in the range of 80 to 100 μm and a width in the range of 700 to 900 μm.

52. A thin film transistor, being formed by the manufacturing method of a thin film transistor according to claim 34.

53. An array substrate comprising the thin film transistor according to claim 52.
